(19) United States
(12) Patent Application Publication
(10) Pub. No.: US 2025/0192115 A1
(43) Pub. Date: Jun. 12, 2025

(54) NON-SINTERED STACKED DEVICE AND PREPARATION METHOD THEREOF, LIGHT-EMITTING SEMICONDUCTOR DEVICE AND PACKAGING METHOD THEREOF

(71) Applicant: FUJIAN LIGHTNING OPTOELECTRONIC CO., LTD., Quanzhou (CN)

(72) Inventors: Yuyuan Li, Quanzhou (CN); Hao Wang, Quanzhou (CN); Cheng Zhu, Quanzhou (CN); Hungyang Lin, Quanzhou (CN); Shenche Lee, Quanzhou (CN); Xihong Wan, Quanzhou (CN)

(21) Appl. No.: 18/813,041

(22) Filed: Aug. 23, 2024

(30) Foreign Application Priority Data
Dec. 6, 2023 (CN) 202311657839.8

(51) Int. Cl. H01L 25/075; H01L 33/46

(52) U.S. Cl. CPC H01L 25/0753; H10H 20/841; H10H 20/034; H10H 20/0361

(57) ABSTRACT

A preparation method of a non-sintered stacked device includes: mixing a first silicone, a first inhibitor, and a first fluoride phosphor to obtain a base layer mixed material; mixing a second silicone, a second inhibitor, and a phosphor to obtain a stacked layer mixed material; coating at least one unit green body in a stacked manner on a surface of a carrier substrate to obtain a formed green body; and curing the formed green body to obtain the non-sintered stacked device; and the curing temperature is a range of 150° C. to 250° C. The preparation method using a non-sintering method has less equipment, simple process and short cycle, and effectively solves the problem of fluoride being sensitive to moisture, the shrinkage and non-forming characteristics of the encapsulant during sintering, achieving the effect of mutual excitation of each layer structure and protection of luminescence of the phosphor.

### TECHNICAL FIELD

The disclosure relates to the field of light-emitting semiconductor technologies, and particularly to a non-sintered stacked device and preparation method thereof, and a light-emitting semiconductor device and packaging method thereof.

### BACKGROUND

In the packaging of light-emitting semiconductors, silicate, yttrium aluminum garnet (YAG), nitride, and other phosphor are commonly used. With the increasing demand for products with high luminous efficacy and high color rendering index, the use of fluoride phosphor has become a key factor. After the addition of fluoride phosphor, the color rendering index can reach above R95, and the brightness can be increased by 10% to 20%. However, despite the advantages of the fluoride phosphor in enhancing brightness and narrowing the full width at half maximum (FWHM), their disadvantages are also significant, such as their sensitivity to moisture. Therefore, in packaging technologies, moisture resistance has become a critical technical challenge.

The Chinese patent with a publication number of CN106219990A, titled “microcrystalline glass for double-layer phosphor base and preparation method thereof”, discloses a method for producing microcrystalline glass for a double-layer phosphor base through steps including sintering, slicing, and fabricating. Specifically, the method includes: S1, accurately weighing raw materials according to a ratio of a glass matrix, placing the raw materials in an agate mortar to mix and grind the raw materials uniformly to obtain raw material powders, then placing the raw material powders into a crucible and heating to melt the raw material powders to obtain a glass melt; S2, removing the glass melt and quickly pour it into a mold to form a block-shaped precursor glass; S3, crushing the obtained precursor glass, grinding the obtained precursor glass uniformly in an agate mortar and adding a phosphor for further grinding to obtain glass powders, and then placing the obtained glass powders in a crucible and heating to melt the glass powders to obtain a glass melt, removing the glass melt, and quickly pour it into a mold to form a block-shaped microcrystalline glass; S4, placing the microcrystalline glass obtained in the S3 into a resistance furnace for annealing to eliminate internal stress, and then obtaining a microcrystalline glass of a required size after cutting and polishing the microcrystalline glass. In the S1, a melting temperature of the raw material powders is 1200° C. to 1300° C., with a holding time of 1 to 3 hours. In the S3, a melting temperature of the glass powders is 650° C. to 700° C., with a holding time of 1 to 3 hours. Although the above technical solution can address the moisture resistance issue of fluoride phosphor, the use of sintered phosphor, whether single-layer, double-layer, or multi-layer film sintering, requires a high-temperature sintering process, which involves high equipment temperatures and poses a significant safety risk.

Moreover, the most critical aspect is that the microcrystalline glass is completed at the glass sintering plant, while semiconductor packaging is carried out at semiconductor packaging companies. Since the color and color temperature of the microcrystalline glass can vary widely, multiple communications and adjustments between the semiconductor packaging companies and the sintering manufacturers are required to achieve the desired color. Additionally, due to the low sintering efficiency, the packaging process for light-emitting semiconductors cannot be independently completed by semiconductor packaging companies, which significantly affects the production efficiency of the semiconductor packaging companies and delays their use of the light-emitting semiconductors.

### SUMMARY

The purpose of the present disclosure is to provide a non-sintered stacked device and preparation thereof, and a light-emitting semiconductor device and packaging method thereof. The non-sintered method adopted by the present disclosure not only has minimal investment in equipment, simple processes, and short cycles, but also effectively solves the problem of fluoride being sensitive to moisture. It also addresses the issue of shrinkage and poor shaping of the encapsulant during sintering, achieving an effect of mutual excitation of each layer structure and protection of luminescence of the phosphor. Moreover, the processes can be completed independently in packaging enterprises.

The present disclosure provides a preparation method for a non-sintered stacked device, including following steps:
mixing a first silicone, a first inhibitor, and a first fluoride phosphor to obtain a base layer mixed material; where the base layer mixed material includes following components in parts by weight: 1 to 35 parts of the first silicone, 1 to 3 parts of the first inhibitor, and 1 to 62 parts of the first fluoride phosphor; and a heat resistance temperature of the first silicone is greater than or equal to 260° C., and an evaporation point of the first inhibitor is less than or equal to 150° C.;
mixing a second silicone, a second inhibitor and a phosphor to obtain a stacked layer mixed material; where the phosphor includes: one or more selected from the group consisting of silicate phosphor, nitride phosphor, aluminate phosphor and second fluoride phosphor; the stacked layer mixed material includes following components in parts by weight: 1 to 25 parts of the second silicone, 1 to 3 parts of the second inhibitor, and 1 to 72 parts of the phosphor; and a heat resistance temperature of the second silicone is greater than or equal to 260° C., and an evaporation point of the second inhibitor is less than or equal to 150° C.;
coating at least one unit green body on a surface of a substrate in a stacked manner to obtain a formed green body; where a preparation method for each unit green body includes: sequentially coating the base layer mixed material and the stacked layer mixed material to form a base layer and a stacked layer respectively to obtain the unit green body; and
curing the formed green body to obtain the non-sintered stacked device; where a curing temperature is in a range of 150° C. to 250° C.

In an embodiment, a wavelength of the first fluoride phosphor is in a range of 625 nanometer (nm) to 635 nm; and
a coating thickness of the base layer mixed material in each unit green body is in a range of 10 micron (μm) to 220 μm.

In an embodiment, wavelengths of the silicate phosphor and the aluminate phosphor are individually in a range of 490 nm to 590 nm; and wavelengths of the second fluoride phosphor and the nitride phosphor are individually in a range of 600 to 675 nm.

In an embodiment, a coating thickness of the stacked layer mixed material in each unit green body is in a range of 10 μm to 300 μm.

In an embodiment, the preparation method further includes: mixing a third silicone and a light-scattering powder to obtain a protective layer mixed material; a heat resistance temperature of the third silicone is greater than or equal to 260° C., and a heat resistance temperature of the light-scattering powder is greater than or equal to 260° C.; and
the preparation method for each unit green body is replaced by: sequentially coating the base layer mixed material, the stacked layer mixed material and the protective layer mixed material to obtain the base layer, the stacked layer, and the protective layer respectively to obtain the unit green body.

In an embodiment, a weight ratio of the third silicone to the light-scattering powder is 90-95:2-5; and
a coating thickness of the protective layer mixed material in each unit green body is in a range of 5 μm to 500 μm.

The non-sintered stacked device obtained by the preparation method provided by the present disclosure, includes: at least one light-emitting unit stacked on the substrate, and each light-emitting unit includes: the base layer and the stacked layer disposed on a surface of the base layer.

In an embodiment, each light-emitting unit further includes: a protective layer disposed on an outer surface of the stacked layer.

A light-emitting semiconductor device provided by the present disclosure, includes:
a carrier substrate;
at least one semiconductor chip disposed on a surface of the carrier substrate;
at least one non-sintered stacked device disposed on a surface of the at least one semiconductor chip;
a reflective wall disposed on the surface of the carrier substrate and surrounding a periphery of the at least one semiconductor chip; and
a powder layer disposed in a closed space defined by the reflective wall; where a height of the powder layer is greater than or equal to a total height of one of the at least one non-sintered stacked device and a corresponding one of the at least one semiconductor chip; where each non-sintered stacked device is the non-sintered stacked device mentioned above.

A packaging method for the light-emitting semiconductor device provided by the present disclosure, includes:
attaching each non-sintered stacked device to the surface of the corresponding semiconductor chip, and attaching each semiconductor chip to the surface of the carrier substrate;
disposing the reflective wall by using a reflective wall material on the surface of the carrier substrate along the periphery of the at least one semiconductor chip; and
filling the closed space defined by the reflective wall with a powder material to obtain the powder layer, and obtaining the light-emitting semiconductor device; where the height of the powder layer is greater than or equal to the total height of the one non-sintered stacked device and the corresponding semiconductor chip.

The present disclosure provides a preparation method for a non-sintered stacked device, including following steps: mixing a first silicone, a first inhibitor, and a first fluoride phosphor to obtain a base layer mixed material; where the base layer mixed material includes following components in parts by weight: 1 to 35 parts of the first silicone, 1 to 3 parts of the first inhibitor, and 1 to 62 parts of the first fluoride phosphor; and a heat resistance temperature of the first silicone is greater than or equal to 260° C., and an evaporation point of the first inhibitor is less than or equal to 150° C.; mixing a second silicone, a second inhibitor and a phosphor to obtain a stacked layer mixed material; where the phosphor includes: one or more selected from the group consisting of silicate phosphor, nitride phosphor, aluminate phosphor and second fluoride phosphor; the stacked layer mixed material includes following components in parts by weight: 1 to 25 parts of the second silicone, 1 to 3 parts of the second inhibitor, and 1 to 72 parts of the phosphor; and a heat resistance temperature of the second silicone is greater than or equal to 260° C., and an evaporation point of the second inhibitor is less than or equal to 150° C.; coating at least one unit green body on a surface of a substrate in a stacked manner to obtain a formed green body; where a preparation method for each unit green body includes: sequentially coating the base layer mixed material and the stacked layer mixed material to form a base layer and a stacked layer respectively to obtain the unit green body; and curing the formed green body to obtain the non-sintered stacked device; where a curing temperature is in a range of 150° C. to 250° C. The preparation method provided by the present disclosure utilizes the encapsulant (including the first silicone and the second silicone) with excellent heat resistance. When using a non-sintered method, the encapsulant will not decompose or volatilize during the curing process. The first and second inhibitors can prevent the self-combination of the first and second silicones during coating, thus achieving excellent bonding and shaping properties. After coating and during a curing process, the first and second inhibitors also help to release internal stress of the first and second silicones without causing shrinkage. Meanwhile, during the curing process, the first and second inhibitors volatilize, allowing the first and second silicones to solidify the phosphor in the base layer and the silicate phosphor in the stacked layer into an integral structure. The phosphor in the stacked layer protects the fluoride phosphor in the base layer and can also interact with the fluoride phosphor in the base layer to excite each other. By this, a problem of the fluoride phosphor being sensitive to moisture is effectively solved. After light exposure, a color concentration of the device prepared by the present disclosure meets the requirements. In summary, the non-sintered method adopted by the present disclosure effectively solves the problem of fluoride phosphor being sensitive to moisture, with minimal investment in equipment, simple processes, and short cycles. It also addresses the issue of shrinkage and poor shaping of the encapsulant during sintering, achieving an effect of mutual excitation of each layer structure and protection of luminescence of the phosphor. Moreover, since sintering is not required, the processes can be completed independently in packaging enterprises. The results of embodiments show that the cost of the non-sintered stacked device prepared by the method provided by the present disclosure is reduced by 80% to 90% compared to market prices of finished products, effectively reducing material waste and production costs. Additionally, the adjusting and production cycle time for the light-emitting semiconductor device have been shortened from 45 days to within 3 days.

Furthermore, in the present disclosure, a wavelength of the first fluoride phosphor is in a range of 625 nanometer (nm) to 635 nm; and a coating thickness of the base layer mixed material in each unit green body is in a range of 10 micron (μm) to 220 μm. Wavelengths of the silicate phosphor and the aluminate phosphor are individually in a range of 490 nm to 590 nm; wavelengths of the second fluoride phosphor and the nitride phosphor are individually in a range of 600 to 675 nm. A coating thickness of the stacked layer mixed material in each unit green body is in a range of 10 μm to 300 μm. Since the thickness of the base layer and the stacked layer, and the weight ratio of the components in each layer will affect light transmittance when light is irradiated on the non-sintered stacked device, the color concentration requirements of the non-sintered stacked device are met by controlling the light-emitting characteristics, the weight ratio, and the single-layer thicknesses of the raw materials in the base layer mixed material and the stacked layer mixed material.

### BRIEF DESCRIPTION OF DRAWINGS

FIG. 1 illustrates a schematic structural diagram of a non-sintered stacked device prepared by the present disclosure.

FIG. 2 illustrates a schematic structural diagram of a light-emitting semiconductor device prepared by the present disclosure.

Description of reference numerals: 1 carrier substrate; 2 semiconductor chip; 3 non-sintered stacked device; 4 reflective wall; 5 protective powder layer; 6 shading layer; 7 first adhesive; 8 second adhesive; 9 protective layer; 10 stacked layer; 11 base layer.

### DETAILED DESCRIPTION OF EMBODIMENTS

The present disclosure provides a preparation method of a non-sintered stacked device, including following steps.

A first silicone, a first inhibitor and a first fluoride phosphor are mixed to obtain a base layer mixed material. The base layer mixed material includes following components in parts by weight: 1 to 35 parts of the first silicone, 1 to 3 parts of the first inhibitor and 1 to 62 parts of the fluoride phosphor. A heat resistance temperature of the first silicone is greater than or equal to 260° C., and an evaporation point of the first inhibitor is less than or equal to 150° C.

A second silicone, a second inhibitor and a phosphor are mixed to obtain a stacked layer mixed material. The phosphor includes: one or more selected from the group consisting of silicate phosphor, nitride phosphor, aluminate phosphor and second fluoride phosphor. The stacked layer mixed material includes following components in parts by weight: 1 to 25 parts of the second silicone, 1 to 3 parts of the second inhibitor, and 1 to 72 parts of the phosphor. A heat resistance temperature of the second silicone is greater than or equal to 260° C., and an evaporation point of the second inhibitor is less than or equal to 150° C.

At least one unit green body is coated on a surface of a substrate in a stacked manner to obtain a formed green body. A preparation method for each unit green body includes following steps: the base layer mixed material and the stacked layer mixed material are sequentially coated to form a base layer and a stacked layer respectively to obtain the unit green body.

The formed green body is cured to obtain the non-sintered stacked device. A curing temperature is in a range of 150° C. to 250° C.

In the present disclosure, unless otherwise specified, all preparation raw materials/components are commercially available products well-known to those skilled in the art.

The first silicone, the first inhibitor and the first fluoride phosphor are mixed by the present disclosure to obtain the base layer mixed material. The base layer mixed material includes the following components in parts by weight: 1 to 35 parts of the first silicone, 1 to 3 parts of the first inhibitor and 1 to 62 parts of the first fluoride phosphor. The heat resistance temperature of the first silicone is greater than or equal to 260° C., and the evaporation point of the first inhibitor is less than or equal to 150° C. In the present disclosure, the heat resistance temperature of the first silicone is preferably in a range of 260° C. to 300° C. The evaporation point of the first inhibitor is preferably in a range of 100° C. to 150° C. The first silicone is preferably purchased from Shin-Etsu Chemical Co., Ltd or American DuPont, with product models being KER series or OE series. The first inhibitor is preferably purchased from American DuPont, with product models being O series. A wavelength of the first fluoride phosphor is preferably in a range of 625 nm to 635 nm. The base layer mixed material preferably includes the following components in parts by weight: 2 to 30 parts of the first silicone, 1 to 2 parts of the first inhibitor, and 5 to 60 parts of the first fluoride phosphor, more preferably, the base layer mixed material includes the following components in parts by weight: 5 to 25 parts of the first silicone, 1 to 1.5 parts of the first inhibitor, and 10 to 60 parts of the first fluoride phosphor. The present disclosure does not have special requirements for a specific implementation process of the first silicone, the first inhibitor and the first fluoride phosphor being mixed.

The second silicone, the second inhibitor and the phosphor are mixed by the present disclosure to obtain the stacked layer mixed material. The phosphor includes one or more selected from the group consisting of the silicate phosphor, the nitride phosphor, the aluminate phosphor and the second fluoride phosphor. The stacked layer mixed material includes the following components parts by weight: 1 to 25 parts of the second silicone, 1 to 3 parts of the second inhibitor, and 1 to 72 parts of the phosphor. The heat resistance temperature of the second silicone is greater than or equal to 260° C., and the evaporation point of the second inhibitor is less than or equal to 150° C. In the present disclosure, the heat resistance temperature of the second silicone is preferably in a range of 260° C. to 300° C. The evaporation point of the second inhibitor is preferably in a range of 100° C. to 150° C. The second silicone is preferably purchased from Shin-Etsu Chemical Co., Ltd or American DuPont, with product models being KER series or OE series. The second inhibitor is preferably purchased from American DuPont, with product models being O series. Wavelengths of the silicate phosphor and the aluminate phosphor are individually preferably in a range of 490 nm to 590 nm, or more preferably 500 nm to 550 nm. Wavelengths of the nitride phosphor and the second fluoride phosphor are individually preferably in a range of 600 nm to 675 nm, or more preferably 620 nm to 670 nm. In the present disclosure, the phosphor preferably includes one or more selected from the group consisting of the silicate phosphor, the nitride phosphor, the aluminate phosphor, specifically preferably the silicate phosphor. In specific embodiments of the present disclosure, the non-sintered stacked device further includes a protective layer 9 disposed on an outer surface of the stacked layer 10 when the phosphor is preferably the second fluoride phosphor.

In the present disclosure, the stacked layer mixed material preferably includes the following components in parts by weight: 1 to 23 parts of the second silicone, 1 to 2.5 parts of the second inhibitor and 1 to 72 parts of the phosphor. The stacked layer mixed material more preferably includes the following components in parts by weight: 2 to 20 parts of the second silicone, 1 to 2 parts of the second inhibitor and 5 to 72 parts of the phosphor. The present disclosure does not have special requirements for a specific implementation process of the second silicone, the second inhibitor and the phosphor being mixed.

In the present disclosure, the first silicone and the second silicone are preferably silicones with same material.

The at least one unit green body is coated on the surface of the substrate by the present disclosure to form the formed green body after obtaining the base layer mixed material and the stacked layer mixed material. The preparation method for each unit green body includes the following steps: the base layer mixed material and the stacked layer mixed material are sequentially coated to form the base layer and the stacked layer respectively to obtain one unit green body. In specific embodiments of the present disclosure, when one unit green body is preferably coated on the surface of the substrate, the obtained non-sintered stacked device includes a light-emitting unit. The base layer mixed material and the stacked layer mixed material are preferably sequentially coated on the surface of the substrate to obtain the formed green body in the present disclosure. When two or more unit green bodies are preferably coated on the surface of the substrate in a stacked manner, the obtained non-sintered stacked device includes two or more light-emitting units. The base layer mixed material and the stacked layer mixed material are preferably sequentially coated on the surface of the substrate to obtain a unit green body in the present disclosure, and then multiple unit green bodies are repeatedly prepared on a surface of the unit green body to obtain multiple formed green bodies according to the preparation method of the unit green body. In the present disclosure, a single layer coating thickness of the base layer mixed material in each unit green body is preferably in a range of 10-200 μm, more preferably in a range of 50-180 μm, even more preferably in a range of 60-150 μm. A single layer coating thickness of the stacked layer mixed material in each unit green body is in a range of 10-300 μm, more preferably 50-250 μm, even more preferably 100-200 μm. The present disclosure does not have special requirements for a specific implementation process of the coating.

The preparation method of the present disclosure further includes: a third silicone and a light-scattering powder are mixed to obtain a protective layer mixed material. A heat resistance temperature of the third silicone is greater than or equal to 260° C., and a heat resistance temperature of the light-scattering powder is greater than or equal to 260° C. In the present disclosure, the heat resistance temperature of the third silicone is preferably 1300° C., and the heat resistance temperature of the light-scattering powder is preferably in a range of 260° C. to 300° C. In specific embodiments of the present disclosure, the third silicone is preferably purchased from Shin-Etsu Chemical Co., Ltd or American DuPont, with product models being KER series or OE series. The light-scattering powder is preferably purchased from American DuPont, with product models being C series. The light-scattering powder is configured to scatter lights emitted from the phosphor in the base layer and the stacked layer. A weight ratio of the third silicone to the light-scattering powder is 90-95:2-5, more preferably 92-94:2.5-4. The present disclosure does not have special requirements for a specific implementation process of the mixing.

In the present disclosure, the first silicone, the second silicone and the third silicone are preferably silicones with same material.

In the present disclosure, when the preparation method further includes preparing the protective layer mixed material, the preparation method of each unit green body is preferably replaced by: sequentially coating the base layer mixed material, the stacked layer mixed material and the protective layer mixed material to respectively form the base layer, the stacked layer and a protective layer to obtain a unit green body.

The step of sequentially coating the base layer mixed material, the stacked layer mixed material and the protective layer mixed material includes following steps 1.1 to 1.3.

1.1 The first silicone, the first inhibitor, and the first fluoride phosphor are mixed according to a required ratio, and stirred evenly to obtain the base layer mixed material after mixing. Then, the base layer mixed material is vacuumized and defoamed. After completing being vacuumized and defoamed, the base layer mixed material is poured onto a release film for coating. A coating thickness of the base layer mixed material is in a range of 10 to 1000 μm, and can be adjusted according to different colors and requirements. After the coating, the stacked layer mixed material can be coated directly while the base layer is still wet. Alternatively, the base layer mixed material can be baked until semi-dry or fully dry before the stacked layer mixed material is coated. A baking temperature of the base layer mixed material is in a range of 40° C. to 250° C., and a baking time of the base layer mixed material is in a range of 3 min to 240 min.

1.2 Before the stacked layer mixed material is coated, the second silicone, the second inhibitor and the phosphor are also mixed according to a required ratio and stirred evenly to obtain the stacked layer mixed material after mixing. Then, the stacked layer mixed material is vacuumized and defoamed, and is placed until the base layer mixed material is coated. A placing time for the stacked layer mixed material is in a range of 1 min to 120 min.

1.3 Before the protective layer mixed material is coated, the third silicone and the light-scattering powder are also mixed according to a required ratio, and stirred evenly to obtain the protective layer mixed material after mixing. Then, the protective layer mixed material is vacuumized and defoamed, and placed aside until the base layer mixed material and the stacked layer mixed material are coated. The protective layer mixed material is like the stacked layer mixed material, the stacked layer mixed material can be coated directly while the base layer is still wet. Alternatively, the base layer mixed material can be baked until semi-dry or fully dry before the stacked layer mixed material is coated. A baking temperature of the base layer mixed material is in a range of 40° C. to 250° C., and a baking time is of the base layer mixed material in a range of 3 min to 240 min.

The baking and placing conditions for above three layers can be adjusted according to silicones' characteristic curve and a particle size of the phosphor. The stacked manner is not limited to the base layer first, the stacked layer second, and finally the protective layer, as long as it is within this concept, it falls within the scope of this design method.

When one unit green body is preferably coated on the surface of the substrate, the obtained non-sintered stacked device includes a light-emitting unit. The base layer mixed material, the stacked layer mixed material and the protective layer are preferably sequentially coated on the surface of the substrate to obtain the formed green body in the present disclosure. When two or more unit green bodies are preferably coated on the surface of the substrate in a stacked manner, the obtained non-sintered stacked device includes two or more light-emitting units in the present disclosure. The base layer mixed material, the stacked layer mixed material and the protective layer mixed material are preferably sequentially coated on the surface of the substrate to obtain a unit green body in the present disclosure, and then multiple unit green bodies are repeatedly prepared on a surface of the unit green body to obtain multiple formed green bodies according to the preparation method of the unit green body. In the present disclosure, a single layer coating thickness of the protective layer mixed material in each unit green body is preferably in a range of 5 to 500 μm, more preferably in a range of 50 to 450 μm, even more preferably in a range of 100 to 400 μm. The present disclosure does not have special requirements for a specific implementation process of the coating.

After the formed green body is obtained, the formed green body is cured in the present disclosure to obtain the non-sintered stacked device. In the present disclosure, a curing temperature is in a range of 150° C. to 250° C., preferably in a range of 160° C. to 200° C., even more preferably 170° C. to 190° C. A curing time is preferably in a range of 5 minute (min) to 60 min, more preferably 10 min to 50 min, even more preferably in a range of 20 min to 40 min. The step of curing the formed green body preferably includes: placing the formed green body and the substrate on a glass, and heating the formed green body and the substrate to cure. The formed green body and the substrate are preferably cured in an oven, and wind from the oven does not blow directly to the formed green body.

After curing, the present disclosure preferably includes a product inspection for the cured product (i.e., non-sintered stacked device). The product inspection includes sequentially conducting a uniformity test. The uniformity test is preferably performed by using a planarity tester to measure a uniformity of the cured product, with the uniformity of the non-sintered stacked device in a range of 1 μm to 5 μm, and the product is considered qualified upon acceptance.

In the present disclosure, the product inspection preferably further includes a blue light activation test. In the present disclosure, the blue light activation test is preferably conducted after the uniformity test. The blue light activation test is preferably performed by: adhering the obtained non-sintered stacked device onto a glass, placing the non-sintered stacked device adhered on the glass on a light source instrument that emits blue light, and performing the X, Y test to determine whether the non-sintered stacked device meets adjusting requirements.

In the present disclosure, after the uniformity test is completed, packaged finished products, semi-finished products and other instruments can be selected for the X,Y test according to different requirements of packaging and product, the present disclosure is not limited to the blue light activation test.

In the present disclosure, after the product inspection is completed, the non-sintered stacked device that meets requirements is preferably covered with a transparent sheet to prevent contamination. Meanwhile, a manufacturing date, a product information and a quick response (QR) code is adhered to a lower left corner of the substrate and the substrate is stored. The packaging factory can perform matching operations based on requirements of inputting products.

Compared to the preparation method of the sintered stacked device in the related art requires more devices, processes and longer cycles, in the preparation method of the non-sintered stacked device provided by the present disclosure, devices invested are an oven, a coater, a blue light tester and a thickness tester (for uniformity test), all these devices are easily achievable in packaging enterprises.

The non-sintered stacked device with good luminous performance and moisture resistance is obtained by controlling types of raw materials, weight ratio of the raw materials, evaporation point of the first and second inhibitors, and heat resistance temperatures of the first, second and third silicones of each layer of the non-sintered stacked device in the preparation method. In the present disclosure, a size of the non-sintered stacked device is capable of being cutting according to a size of a product. The non-sintered stacked device prepared by the present disclosure is capable of being applied to all types of semiconductor visible and invisible light uses, not limited to being attached to light-emitting surfaces of chips or devices.

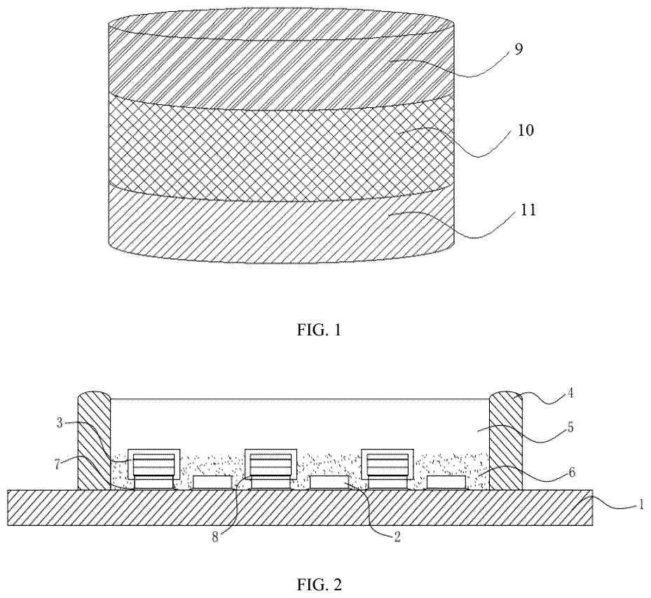

As illustrated in FIG. 1, the non-sintered stacked device obtained by the preparation method described in the above technical solution provided by the present disclosure includes multiple light-emitting units stacked on the substrate, with each light-emitting unit including one base layer 11 and one stacked layer 10 disposed on a surface of the one substrate 11.

In the present disclosure, the light-emitting unit further includes one protective layer 9 disposed on an outer surface of the stacked layer 10.

In the present disclosure, the stacked layer 10 is configured to perform mutual excitation with the phosphor in the base layer 11, thereby enhancing brightness and effectively protecting the phosphor in the base layer 11 from moisture sensitivity. The present disclosure provides the protective layer 9 on the surface of the stacked layer 10, which can form a protective barrier for fluoride in the stacked layer 10 and the base layer 11, preventing moisture from affecting the fluorides in the stacked layer 10 and the base layer 11, and improving the moisture resistance of the fluorides in the stacked layer 10 and the base layer 11.

The base layer 11 is configured to allow the fluoride, which is not easily penetrable and prone to light loss, and is not moisture-resistant, to be excited with a chip. A strongest light and temperature from the chip is capable of preferentially exciting and protecting the fluoride.

As illustrated in FIG. 2, the present disclosure provides a light-emitting semiconductor device, including a carrier substrate 1, at least one semiconductor chip 2 disposed on a surface of the carrier substrate 1, at least one non-sintered stacked device 3 disposed on a surface of the at least one semiconductor chip 2, a reflective wall 4 disposed on the surface of the carrier substrate 1 and surrounding a periphery of the at least one semiconductor chip 2, and a powder layer disposed in a closed space defined by the reflective wall 4. A height of the powder layer is greater than or equal to a total height of the non-sintered stacked device and the semiconductor chip 2. Each non-sintered stacked device 3 is the non-sintered stacked device described in the above technical solution.

The light-emitting semiconductor device provided by the present disclosure includes the carrier substrate 1. The material of the carrier substrate 1 is preferably aluminum nitride, alumina, resin or another material with good heat dissipation properties.

The light-emitting semiconductor device provided by the present disclosure includes at least one semiconductor chip 2 disposed on the surface of the carrier substrate 1. In the present disclosure, a number of the at least one semiconductor chip 2 on the surface of the carrier substrate 1 is preferably in a range of 1 piece to 100,000 pieces, more preferably in a range of 1 piece to 1,000 pieces.

The light-emitting semiconductor device provided by the present disclosure includes the at least one non-sintered stacked device 3 disposed on a surface of the at least one semiconductor chip 2, each non-sintered stacked device 3 is the non-sintered stacked device described in the above technical solution. The non-sintered stacked device 3 is preferably disposed on the surface of each semiconductor chip 2, or the non-sintered stacked devices 3 are preferably disposed on the surfaces of some of the semiconductor chips 2. A number of the non-sintered stacked device 3 is smaller than or equal to a number of the semiconductor chip 2.

The light-emitting semiconductor device provided by the present disclosure includes a reflective wall 4 disposed on the surface of the carrier substrate 1 and surrounding the periphery of the at least one semiconductor chip 2. In the present disclosure, the reflective wall 4 may be a multi-layer reflective wall in the height direction, forming multi-layer reflection, or a wall with a short lower reflective wall, a high second layer, to achieve different reflection and focusing effects.

The material of the reflective wall 4 is preferably a white reflective material. In specific embodiments of the present disclosure, the material of the reflective wall 4 is specifically preferably white silicone. The height of the reflective wall 4 is preferably in a range of 0.1 mm to 1 centimeter (cm), more preferably in a range of 0.2 mm to 0.5 cm. The reflective wall 4 is configured to serve as protection, reflection, focusing, and reducing the light-emitting surface.

The light-emitting semiconductor device provided by the present disclosure includes the powder layer disposed in the closed space defined by the reflective wall 4. The height of the powder layer is greater than or equal to the total height of the non-sintered stacked device 3 and the corresponding semiconductor chip 2. In the present disclosure, when the powder is a mixture of a light-blocking powder and a protective powder, the powder layer is a mixed layer of the light-blocking powder and the protective powder. When the powder is an independent light-blocking powder or an independent protective powder, the powder layer includes a shading layer 6 (also referred to as light-blocking powder layer) and a protective powder layer 5 disposed on an upper surface of the shading layer 6. A thickness of the shading layer 6 is preferably in a range of 5 μm to 1 cm, more preferably 10 μm to 1 mm. In the present disclosure, the light-blocking powder is preferably a phosphor powder or a white powder, a material of the phosphor powder is specifically preferably nitride. A material of the white powder is specifically preferably high-temperature-resistant titanium dioxide. A material of the protective powder layer 5 is specifically preferably high-temperature-resistant silicone. The powder layer is preferably configured to protect the non-sintered stacked device 3.

In the present disclosure, the height of the powder layer is greater than or equal to the total height of the non-sintered stacked device 3 and the semiconductor chip 2, this can be understood as the height of the powder layer being greater than or equal to the maximum value of the total heights of the non-sintered stacked devices 3 and the corresponding semiconductor chips 2. The height of the reflective wall is greater than or equal to the height of the powder layer.

The present disclosure provides a packaging method for the light-emitting semiconductor device described in the above technical solution, which includes the following steps.

Each non-sintered stacked device 3 is attached to the surface of the corresponding semiconductor chip 2. Each semiconductor chip 2 is attached to the surface of the carrier substrate 1.

The reflective wall 4 is disposed by using a reflective wall material on the surface of the carrier substrate 1 along the periphery of the at least one semiconductor chip 2.

The powder material is filled in the closed space defined by the reflective wall 4 to obtain the powder layer. The light-emitting semiconductor device is obtained. The height of the powder layer is greater than or equal to the total height of the non-sintered stacked device 3 and the corresponding semiconductor chip 2.

In the present disclosure, the at least one non-sintered stacked device 3 described in the above technical solution is adhered onto the surface of the at least one semiconductor chip 2. The at least one semiconductor chip 2 is attached to the surface of the carrier substrate 1. The semiconductor chip 2 is attached to the surface of the carrier substrate 1 preferably using a first adhesive. The first adhesive has a same material and shrinkage properties as the first and second silicones, avoiding issues caused by different materials having different adhesive shrinkage properties. The at least one non-sintered stacked device 3 is attached to the surface of the at least one semiconductor chip preferably using a second adhesive. The second adhesive has the same material and shrinkage properties as the first and second silicones, avoiding issues caused by different materials having different adhesive shrinkage properties. In a specific embodiment of the present disclosure, each semiconductor chip 2 is attached to one non-sintered stacked device 3.

The reflective wall is disposed along the periphery of the semiconductor chip 2 and on the surface of the carrier substrate 1 using the reflective wall material. The present disclosure does not have special requirements for the specific method of disposing the reflective wall.

The powder material is filled in the closed space defined by the reflective wall to obtain the powder layer. The height of the powder layer is greater than or equal to the total height of the non-sintered stacked device 3 and the corresponding semiconductor chip 2, thereby obtaining the light-emitting semiconductor device.

To further illustrate the present invention, the technical solutions provided by the present disclosure are described in detail below in conjunction with embodiments, but they should not be construed as limiting the scope of protection of the present disclosure.

### Embodiment 1

The method for preparing the non-sintered stacked device according to the structural schematic diagram of the non-sintered stacked device as illustrated in FIG. 1, includes the following steps.

35 part of silicones (American DuPont, OE series), 3 parts of inhibitor (American Dupont, O series), 62 parts of the fluoride phosphor (with the wavelength in a range of 625 nm to 635 nm) are poured into a rubber cup and then mixed to obtain the base layer mixed material.

25 parts of silicone (American DuPont, OE series), 3 parts of inhibitors (American DuPont, O series), 72 parts of one or more (wavelength 600 nm to 675 nm) selected from the group consisting of silicate phosphor, aluminate phosphor (with wavelengths in a range of 490 nm to 590 nm), fluoride phosphor, and nitride phosphor are poured into a rubber cup and then mixed to obtain the stacked layer mixed material.

Silicones in weight of 95 gram (g) (American DuPont, OE series) and a light-scattering powder in weight of 5 g (American DuPont, C series) are poured into a rubber cup and then mixed to obtain the protective layer mixed material.

The substrate is placed in the coating device, the base layer mixed material, the stacked layer mixed material and the protective layer mixed material are sequentially coated. The coating thickness of the base layer mixed material is 200 μm, the coating thickness of the stacked layer mixed material is 300 μm, and the coating thickness of the protective layer mixed material is 500 μm.

After the coating, the substrate is placed on the glass and placed in the oven to be heated and baked. The wind of the oven should not blow directly to the substrate. The heating temperature is 200° C., and the heating time is 60 min.

After the baking, the obtained product is placed on the planarity tester to measure a uniformity (thickness test) of the non-sintered stacked device. Those obtained products with uniformities in a range of 1 μm to 5 μm are qualified products.

After the thickness test, the non-sintered stacked device is attached to the glass and then placed on the light source instrument that emits blue light, and the X, Y test is conducted.

After the requirements are met, the non-sintered stacked device is covered with a transparent sheet to prevent contamination. Meanwhile, the manufacturing date, the product information and the QR code are adhered to a lower left corner of the non-sintered stacked device and the non-sintered stacked device is stored. The packaging factory can perform matching operations based on requirements of the inputting products.

### Embodiment 2

The method for preparing the light-emitting semiconductor according to the structural schematic diagram of the light-emitting semiconductor as illustrated in FIG. 2, includes following steps.

The non-sintered stacked device prepared in the embodiment 1 is attached to a surface of the semiconductor chip using a silicone (American DuPont, OE series). The number of the semiconductor chip is in a range of 1 piece to 1000 pieces. The number of the non-sintered stacked device is in a range of 1 piece to 1000 pieces.

The single semiconductor chip finishing the attaching is attached to the surface of the carrier substrate using silicones (American DuPont, OE series). The material of the carrier substrate is aluminum nitride, and the semiconductor chips can be freely arranged in series or parallel on the carrier substrate.

After the attaching of the carrier substrate is completed, the reflective wall material is utilized to build the corresponding reflective wall surrounding the semiconductor chips and on the surface of the carrier substrate with a height of 1 cm.

After the reflective wall is accomplished, a layer of a phosphor (the material of the phosphor includes a high-temperature-resistant phosphor powder material and a silicone with a temperature resistance greater than or equal to 260° C.) with a thickness of 0.5 cm is firstly added, and then a layer of a protective powder (the material of the protective powder includes any one of protective materials including SiO₂, AlO₂, titanium dioxide, high-reflectivity white powder, and white silicone, or a mixture of the protective materials) with a thickness of 0.5 cm is added according to the structure illustrated in FIG. 2. The light-emitting semiconductor device as illustrated in FIG. 2 is obtained.

### Test Example 1

A waterproof performance of the non-sintered stacked device prepared in the embodiment 1 is tested using a MSLa2 method, and a test result is in compliance with grade 2a (no greater than 30° C./60% relative humidity (RH)).

### Test Example 2

A luminous performance of the non-sintered stacked device prepared in the embodiment 1 is tested. A testing method is spatial spectral distribution values: dx value is no greater than 0.012, dy is no greater than 0.015, a COA test value: du′v′ is no greater than 0.008, and a COS test value: du′v′ is no greater than 0.008 (COA refers to color of angle, COS refers to color of surface).

### Test Example 3

Various tests are conducted on the light-emitting semiconductor device prepared in the embodiment 2: high-temperature aging: 3000 hour (H), the light attenuation (i.e., light decay) is no greater than 10%; high-temperature and high humidity aging: 3000 H, the light attenuation is no greater than 10%; 1000 drops: no damage; red ink test: no leakage of red ink into a product functional area after 48 H; cold and hot shock test: −45° C. to +125° C., no dead light for 1000 cycles.

From above embodiments, it can be inferred that solving the problem of the non-sintered stacked device outsourcing in the present disclosure is equivalent to solving the critical core “bottleneck” problem, and semiconductor chip packaging factories do not need the non-sintered stacked device outsourcing. The cost of a single non-sintered stacked device prepared by the present disclosure is reduced by 80% to 90% compared to a purchase price, effectively reducing material waste and production costs. The adjusting and production cycle time has been changed from 45 days to within 3 days. It does not require investment of manufacturing equipment, environmental impact assessment equipment, manpower, etc. like sintering methods. Non-sintered devices attaching to inner sides of semiconductor devices, selectively attaching non-sintered devices of different colors can emit multiple different or same light.

Although the above embodiments provide a detailed description of the present disclosure, they are only a part of the embodiments, not all of them. Other embodiments can also be obtained without creativity based on the present embodiment, all of which fall within the scope of protection of the present disclosure.

What is claimed is:

1. A preparation method for a non-sintered stacked device, comprising following steps:
mixing a first silicone, a first inhibitor, and a first fluoride phosphor to obtain a base layer mixed material; wherein the base layer mixed material comprises following components in parts by weight: 1 to 35 parts of the first silicone, 1 to 3 parts of the first inhibitor, and 1 to 62 parts of the first fluoride phosphor; and a heat resistance temperature of the first silicone is greater than or equal to 260° C., and an evaporation point of the first inhibitor is less than or equal to 150° C.;
mixing a second silicone, a second inhibitor and a phosphor to obtain a stacked layer mixed material; wherein the phosphor comprises: one or more selected from the group consisting of silicate phosphor, nitride phosphor, aluminate phosphor and second fluoride phosphor; the stacked layer mixed material comprises following components in parts by weight: 1 to 25 parts of the second silicone, 1 to 3 parts of the second inhibitor, and 1 to 72 parts of the phosphor; and a heat resistance temperature of the second silicone is greater than or equal to 260° C., and an evaporation point of the second inhibitor is less than or equal to 150° C.;
coating at least one unit green body on a surface of a substrate in a stacked manner to obtain a formed green body; wherein a preparation method for each unit green body comprises: sequentially coating the base layer mixed material and the stacked layer mixed material to form a base layer and a stacked layer respectively to obtain the unit green body; and
curing the formed green body to obtain the non-sintered stacked device; wherein a curing temperature is in a range of 150° C. to 250° C.

2. The preparation method as claimed in claim 1, wherein a wavelength of the first fluoride phosphor is in a range of 625 nanometer (nm) to 635 nm; and
a coating thickness of the base layer mixed material in each unit green body is in a range of 10 micron (μm) to 220 μm.

3. The preparation method as claimed in claim 1, wherein wavelengths of the silicate phosphor and the aluminate phosphor are individually in a range of 490 nm to 590 nm; and
wavelengths of the second fluoride phosphor and the nitride phosphor are individually in a range of 600 to 675 nm.

4. The preparation method as claimed in claim 1, wherein a coating thickness of the stacked layer mixed material in each unit green body is in a range of 10 μm to 300 μm.

5. The preparation method as claimed in claim 1, wherein the preparation method further comprises: mixing a third silicone and a light-scattering powder to obtain a protective layer mixed material;
a heat resistance temperature of the third silicone is greater than or equal to 260° C., and a heat resistance temperature of the light-scattering powder is greater than or equal to 260° C.;
the preparation method for each unit green body is replaced by: sequentially coating the base layer mixed material, the stacked layer mixed material and the protective layer mixed material to obtain the base layer, the stacked layer, and the protective layer respectively to obtain the unit green body.

6. The preparation method as claimed in claim 5, wherein a weight ratio of the third silicone to the light-scattering powder is 90-95:2-5; and
a coating thickness of the protective layer mixed material in each unit green body is in a range of 5 μm to 500 μm.

7. The non-sintered stacked device obtained by the preparation method as claimed in claim 1, comprising: at least one light-emitting unit stacked on the substrate, wherein each light-emitting unit comprises: the base layer (11) and the stacked layer (10) disposed on a surface of the base layer (11).

8. The non-sintered stacked device as claimed in claim 7, wherein each light-emitting unit further comprises: a protective layer (9) disposed on an outer surface of the stacked layer (10).

9. A light-emitting semiconductor device, comprising:
a carrier substrate (1);
at least one semiconductor chip (2) disposed on a surface of the carrier substrate (1);
at least one non-sintered stacked device (3) disposed on a surface of the at least one semiconductor chip (2);
a reflective wall (4) disposed on the surface of the carrier substrate (1) and surrounding a periphery of the at least one semiconductor chip (2); and
a powder layer disposed in a closed space defined by the reflective wall; wherein a height of the powder layer is greater than or equal to a total height of one of the at least one non-sintered stacked device (3) and a corresponding one of the at least one semiconductor chip (2);
wherein each non-sintered stacked device (3) is the non-sintered stacked device as claimed in claim 7.

10. A packaging method for the light-emitting semiconductor device as claimed in claim 9, comprising:
attaching each non-sintered stacked device to the surface of the corresponding semiconductor chip (2), and attaching each semiconductor chip (2) to the surface of the carrier substrate (1);
disposing the reflective wall (4) by using a reflective wall material on the surface of the carrier substrate (1) along the periphery of the at least one semiconductor chip (2); and
filling the closed space defined by the reflective wall (4) with a powder material to obtain the powder layer, and obtaining the light-emitting semiconductor device; wherein the height of the powder layer is greater than or equal to the total height of the one non-sintered stacked device (3) and the corresponding semiconductor chip (2).
